(19) United States
(12) Patent Application Publication
(10) Pub. No.: US 2026/0211312 A1
(43) Pub. Date: Jul. 23, 2026

(54) STORAGE CONTAINER OPENING/CLOSING DEVICE AND STORAGE CONTAINER OPENING/CLOSING METHOD

(71) Applicant: LINTEC Corporation, Tokyo (JP)

(72) Inventor: Takuya HAYASAKA, Tokyo (JP)

(21) Appl. No.: 19/438,979

(22) Filed: Jan. 2, 2026

(30) Foreign Application Priority Data
Jan. 21, 2025 (JP) 2025-008653

(51) Int. Cl. G03F 1/66

(52) U.S. Cl. CPC G03F 1/66

(57) ABSTRACT

A storage container opening/closing device includes: a storage portion configured to house a frame member to which a pellicle film is attached; a cover configured to cover the storage portion; a storage container support unit configured to support the storage container; and an opening/closing unit configured to open and close the storage container by moving the cover, in which the opening/closing unit includes: a retainer configured to retain the cover; a first movement unit configured to move the cover retained by the retainer in a direction away from and toward the storage portion; and a second movement unit configured to tilt the cover retained by the retainer with respect to the storage portion.

### CROSS REFERENCE TO RELATED APPLICATIONS

The entire disclosure of Japanese Patent Application No. 2025-008653 filed Jan. 21, 2025 is expressly incorporated by reference herein.

### TECHNICAL FIELD

The present invention relates to a storage container opening/closing device and a storage container opening/closing method.

### BACKGROUND ART

A device for opening and closing a storage container that houses a frame member to which a pellicle film is attached is known (see, for example, Literature 1: JP H9-138498 A).

In a pellicle automatic attachment device (storage container opening/closing device) described in Literature 1, a cover opening/closing unit 10 (opening/closing unit) opens the storage container by lifting a cover 15 (cover) of a frame case (storage container) upward. Therefore, in a case where the storage container is of a type in which a part of the cover is connected to a tray portion 14 (storage portion) that houses a pellicle-attached frame 16 (frame member), the cover cannot be separated from the storage portion, and thus the storage container cannot be opened, which results in a disadvantage.

### SUMMARY OF THE INVENTION

An object of the invention is to provide a storage container opening/closing device and a storage container opening/closing method that are capable of opening a storage container even in a case of a storage container in which a part of a cover is connected to a storage portion that houses a frame member.

An aspect of the invention employs a configuration set forth in the appended claims.

According to the aspect of the invention, a cover retained by a retainer is tilted with respect to a storage portion. Therefore, even in a case of a storage container in which a part of the cover is connected to the storage portion that houses a frame member, the cover can be separated from the storage portion to open the storage container.

### BRIEF DESCRIPTION OF DRAWINGS

FIG. 1A is a schematic diagram of a storage container opening/closing device according to an exemplary embodiment of the invention.

FIG. 1B is another schematic diagram of the storage container opening/closing device according to the exemplary embodiment of the invention.

FIG. 1C is still another schematic diagram of the storage container opening/closing device according to the exemplary embodiment of the invention.

FIG. 2A is a schematic diagram of a storage container opening/closing device according to a modification of the invention.

FIG. 2B is another schematic diagram of the storage container opening/closing device according to the modification of the invention.

### DETAILED DESCRIPTION

An exemplary embodiment of the invention will be described below with reference to the attached drawings.

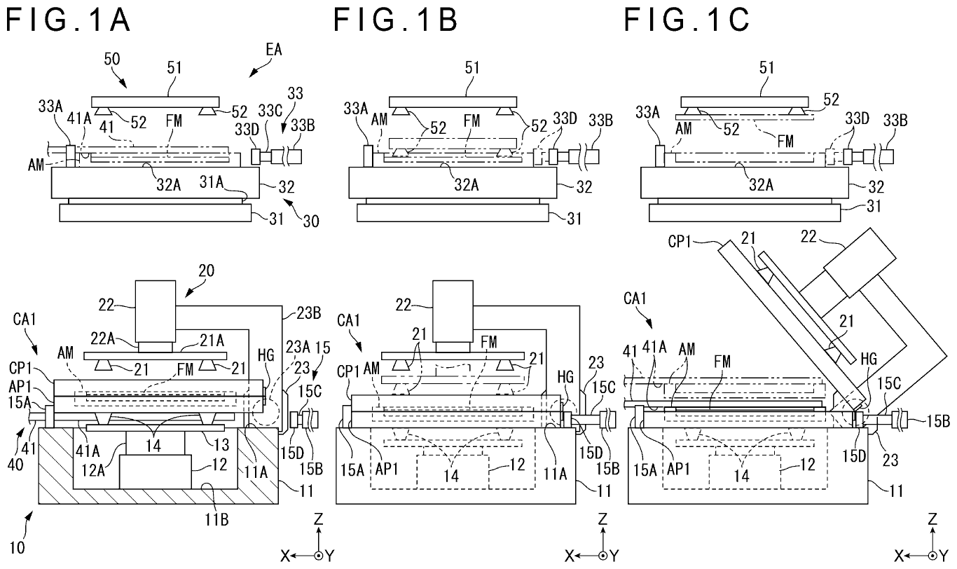

An X-axis, a Y-axis, and a Z-axis in the exemplary embodiment are orthogonal to each other, and the X-axis and the Y-axis are defined as axes in a predetermined plane while the Z-axis is defined as an axis orthogonal to the predetermined plane. Furthermore, in the exemplary embodiment, when viewed from a front side in a direction parallel to the Y-axis of FIG. 1A as a reference, an arrow direction of the Z-axis is defined as an “upward” direction and the opposite direction is defined as a “downward” direction; an arrow direction of the X-axis is defined as a “left” direction and the opposite direction is defined as a “right” direction; and the direction parallel to the Y-axis toward the front side of FIG. 1A is defined as a “front” direction and the opposite direction is defined as a “rear” direction.

A storage container opening/closing device EA is a device for opening and closing a storage container CA1 including: a storage portion AP1 that houses a frame member FM to which a pellicle film is attached; and a cover CP1 that covers the storage portion AP1. The storage container opening/closing device EA includes: a storage container support unit 10 that performs a storage container supporting step for supporting the storage container CA1; an opening/closing unit 20 that performs an opening/closing step for opening and closing the storage container CA1 by moving the cover CP1; a storage member support unit 30 that performs a storage member supporting step for supporting the frame member FM and a storage member AM; and a transport unit 40 that performs a transport step for taking the frame member FM and the storage member AM out of the storage container CA1 and transporting the frame member FM and the storage member AM to the storage member support unit 30, which are located near a transfer unit 50 that performs a transfer step for transferring the storage member AM.

It should be noted that the storage container CA1 is configured such that a part of the cover CP1 is connected to the storage portion AP1 via a connecting portion HG such as a hinge or a shaft member, which allows the storage container CA1 to be opened from one side with the connecting portion HG as a rotation center. The frame member FM is housed in the storage portion AP1 by means of the storage member AM that houses the frame member FM.

The storage container support unit 10 includes: a table 11 having a recess 11B in a support surface 11A that supports the storage container CA1; a linear motion motor 12 serving as drive equipment disposed in the recess 11B; a platform 13 supported by an output shaft 12A of the linear motion motor 12; a suction pad(s) 14 supported by the platform 13 and serving as a retaining member capable of retention by suction by means of a decompressor (not illustrated) such as a decompression pump or a vacuum ejector; and a positioning unit 15 that positions the storage container CA1.

The positioning unit 15 includes: a pin 15A provided on the support surface 11A; a linear motion motor 15B serving as drive equipment; and an abutment member 15D that is supported by an output shaft 15C of the linear motion motor 15B and is abutted against the storage container CA1 to press the storage container CA1 against the pin 15A.

The opening/closing unit 20 includes: a suction pad(s) 21 capable of retention by suction by means of a decompressor (not illustrated) such as a decompression pump or a vacuum ejector and serving as a retainer that performs a retaining step for retaining the cover CP1; a linear motion motor 22 supporting an arm 21A supporting the suction pad 21 via an output shaft 22A, the linear motion motor 22 serving as drive equipment and being a first movement unit that performs a first movement step for moving the cover CP1 retained by the suction pad 21 in a translational manner in an up-and-down direction, i.e., a direction away from and toward the storage portion AP1; and a rotary motor 23 supporting a bracket 23B supporting the linear motion motor 22 via an output shaft 23A, the rotary motor 23 serving as drive equipment and being a second movement unit that performs a second movement step for tilting the cover CP1 retained by the suction pad 21 with respect to the storage portion AP1.

The storage member support unit 30 includes: a rotary motor 31 serving as drive equipment; a table 32 supported by an output shaft 31A of the rotary motor 31 and having a retaining surface 32A capable of retention by suction by means of a decompressor (retainer) (not illustrated) such as a decompression pump or a vacuum ejector; and a positioning unit 33 that positions the storage container CA1.

The positioning unit 33 includes: a pin 33A provided on the retaining surface 32A; a linear motion motor 33B serving as drive equipment; and an abutment member 33D that is supported by an output shaft 33C of the linear motion motor 33B and is abutted against the storage container CA1 to press the storage container CA1 against the pin 33A.

The transport unit 40 includes a transport arm 41 movably supported by drive equipment (not illustrated) such as an articulated robot and having a retaining surface 41A capable of retention by suction by means of a decompressor (retainer) (not illustrated) such as a decompression pump or a vacuum ejector.

The transfer unit 50 includes a transfer arm 51 movably supported by drive equipment (not illustrated) such as an articulated robot; and a suction pad(s) 52 supported by the transfer arm 51 and serving as a retaining member capable of retention by suction by means of a decompressor (not illustrated) such as a decompression pump or a vacuum ejector.

Operations of the storage container opening/closing device EA described above will be described.

First, a user of the storage container opening/closing device EA (hereinafter, simply referred to as a “user”) inputs a signal for starting an automatic operation by means of an operation unit (not illustrated) such as an operation panel or a personal computer to the storage container opening/closing device EA in which the members are respectively disposed at initial positions shown by solid lines in FIG. 1A. Next, the transport unit 40 drives drive equipment (not illustrated) to place the storage container CA1 on the suction pad 14 using the transport arm 41 as illustrated in FIG. 1A.

Subsequently, the storage container support unit 10 drives a decompressor (not illustrated) to start retaining the storage container CA1 by suction with the suction pad 14. After that, the transport unit 40 drives drive equipment (not illustrated) to retract the transport arm 41.

Next, the storage container support unit 10 drives the linear motion motor 12 to lower the storage container CA1 to be supported on the support surface 11A as illustrated in FIG. 1B. Subsequently, the storage container support unit 10 stops driving the decompressor (not illustrated) to release the retention by suction of the storage container CA1 with the suction pad 14. Then, the storage container support unit 10 drives the linear motion motor 15B to press the storage container CA1 against the pin 15A with the abutment member 15D and position the storage container CA1. Next, the opening/closing unit 20 drives the linear motion motor 22 to lower the suction pad 21 to be abutted against the cover CP1 as shown by chain double-dashed lines in FIG. 1B, and subsequently drives a decompressor (not illustrated) to start retaining the cover CP1 by suction by the suction pad 21.

Subsequently, the opening/closing unit 20 drives the rotary motor 23 to rotate the cover CP1 retained by the suction pad 21, thereby tilting the cover CP1 with respect to the storage portion AP1 as illustrated in FIG. 1C. This causes the cover CP1 to be separated from the storage portion AP1 to open the storage container CA1. Next, the transport unit 40 drives drive equipment (not illustrated) to abut the transport arm 41 against the storage member AM as illustrated in FIG. 1C, and subsequently drives a decompressor (not illustrated) to start retaining the storage member AM by suction with the retaining surface 41A. Then, the transport unit 40 drives drive equipment (not illustrated) to raise the storage member AM housing the frame member FM as shown by chain double-dashed lines in FIG. 1C and place the storage member AM on the retaining surface 32A as shown by chain double-dashed lines in FIG. 1A. Next, the transport unit 40 stops driving the decompressor (not illustrated) to release the retention by suction of the storage member AM with the retaining surface 41A, and subsequently drives drive equipment (not illustrated) to retract the transport arm 41.

Subsequently, the storage member support unit 30 drives the rotary motor 31 to rotate the table 32, thereby positioning the storage member AM in the rotation direction, and subsequently drives the linear motion motor 33B to press the storage member AM against the pin 33A with the abutment member 33D and position the storage member AM in a left-and-right direction as shown by chain double-dashed lines in FIG. 1B. Next, the transfer unit 50 drives drive equipment (not illustrated) and a decompressor (not illustrated) to lower the suction pad 52 and retain the frame member FM by suction with the suction pad 52 as shown by chain double-dashed lines in FIG. 1B. Then, the transfer unit 50 drives drive equipment (not illustrated) to raise the frame member FM as shown by chain double-dashed lines in FIG. 1C, and transfers the frame member FM to the next step such as inspection. Next, after the completion of the processing of the frame member FM in the next step, the storage container opening/closing device EA performs the transfer step, the storage member support step, the transport step, the opening/closing step, and the storage container support step in the reverse order and in reverse procedures to those performed previously. That is, the transfer unit 50 transfers the frame member FM to re-house the frame member FM in the storage member AM, and subsequently, the storage member support unit 30 releases the positioning of the storage member AM with the positioning unit 33 and rotates the table 32 in a reverse direction. Subsequently, the transport unit 40 transports the storage member AM to house the storage member AM in the storage portion AP1, and the opening/closing unit 20 closes the storage container CA1. And then, the storage container support unit 10 releases the positioning of the storage container CA1 with the positioning unit 15 and raises the storage container CA1. Next, the transport unit 40 transports the storage container CA1 to a collecting unit (not illustrated) such as a container stocker or a container collection box. Subsequently, operations similar to those described above are repeated.

According to the above exemplary embodiment, since the cover CP1 retained by the suction pad 21 is tilted with respect to the storage portion AP1, the cover CP1 can be separated from the storage portion AP1 to open the storage container CA1, even in a case of the storage container CA1 in which a part of the cover CP1 is connected to the storage portion AP1 that houses the frame member FM.

The best configuration, method, and the like for carrying out the invention are disclosed in the above description. The invention, however, is not limited thereto. Thus, although the invention is particularly illustrated and described primarily with respect to a specific exemplary embodiment, those skilled in the art may make various modifications to the above exemplary embodiment in terms of shape, material, numerical quantity, and other detailed configurations without departing from the technical idea and the scope of the object of the invention. Further, the descriptions limiting the shapes, materials, and the like disclosed hereinabove are given as examples to facilitate understanding of the invention, and are not intended to limit the invention. Therefore, descriptions in which components are named without some or all of the limitations on shape, material, and the like are within the scope of the invention.

Moreover, the units and steps in the invention are by no means limited as long as the operation, functions, or steps described in connection with the units and steps are achievable, and are in no way limited to the merely exemplary components or steps described in the above exemplary embodiment. For example, the storage container support unit may be any unit capable of supporting the storage container, and is by no means limited insofar as being, in light of common technical knowledge in the art at the time of filing the present application, within a scope of the technical knowledge (the same applies to any other units and steps).

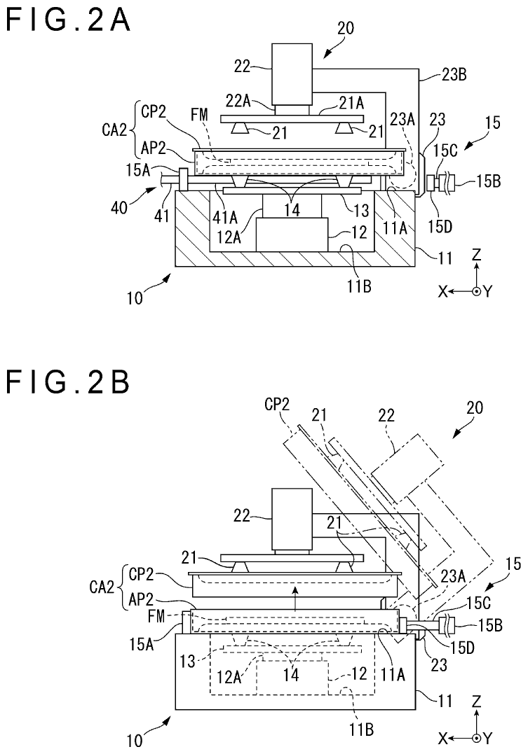

The storage container opening/closing device EA may open and close a storage container CA2 in which a cover CP2 is not connected to a storage portion AP2 but a part of the cover CP2 is housed in the storage portion AP2 as illustrated in FIG. 2A. In this case, the opening/closing unit 20 may be configured to drive the linear motion motor 22 to, as illustrated in FIG. 2B, move the cover CP2 retained by the suction pad 21 upward in a translational manner to separate the cover CP2 from the storage portion AP2 until a lower surface of the cover CP2 is positioned above an upper surface of the storage portion AP2, and subsequently drive the rotary motor 23 to tilt the cover CP2 retained by the suction pad 21 with respect to the storage portion AP2 as shown by chain double-dashed lines in the figure, thereby opening the storage container CA2. It should be noted that the storage container CA2 is configured such that a central portion of the cover CP2 projects downward and a central portion of the storage portion AP2 projects upward, and the frame member FM housed is sandwiched between the central portion of the cover CP2 and the central portion of the storage portion AP2 without the storage member AM. When the storage container opening/closing device EA opens the storage container CA2, the cover CP2 is moved upward in a translational manner and then tilted with respect to the storage portion AP2, whereby a space between the cover CP2 and the storage portion AP2 is further expanded to expand a region where the transport unit 40 is movable in the space. Accordingly, the transport unit 40 and the frame member FM can be restrained from colliding with the cover CP2 and the storage portion AP2 and the frame member FM can be easily taken out of the storage container CA2.

The storage container support unit 10 may be configured such that the support surface 11A is capable of retention by suction by means of a decompressor (not illustrated) (retainer) such as a decompression pump or a vacuum ejector. In this case, the storage container support unit 10 may or may not include the recess 11B, the linear motion motor 12, the platform 13, and the suction pad 14.

The storage container support unit 10 may be configured such that an upper surface of the platform 13, instead of the suction pad 14, is capable of retention by suction by means of a decompressor (not illustrated) (retainer) such as a decompression pump or a vacuum ejector. In this case, the storage container support unit 10 may or may not include the positioning unit 15.

The opening/closing unit 20 may close the storage container CA1, CA2 without re-housing the frame member FM that has been taken out of the storage containers CA1 and CA2. Also, a lower surface of the arm 21A, instead of the suction pad 21, may be made capable of retention by suction by means of a decompressor (not illustrated) (retainer) such as a decompression pump or a vacuum ejector.

When the opening/closing unit 20 opens and closes the storage container CA2, subsequent to the retention by suction of the cover CP2 by the suction pad 21, the opening/closing unit 20 may tilt the cover CP2 with respect to the storage portion AP2 without moving the cover CP2 upward in a translational manner, or may move the cover CP2 upward in a translational manner without tilting the cover CP2 with respect to the storage portion AP2.

The rotary motor 31 and the positioning unit 33 may or may not be provided in the storage member support unit 30.

The storage member support unit 30 may or may not be provided in the storage container opening/closing device EA.

The transport unit 40 may or may not be provided in the storage container opening/closing device EA. In a case where the transport unit 40 is not provided, another device may transport the frame member FM and the storage member AM.

The transfer unit 50 does not necessarily re-house, in the storage member AM, the frame member FM that has been transferred to the next step. The transfer unit 50 may or may not be provided in the storage container opening/closing device EA. In a case where the transfer unit 50 is not provided, another device may transfer the frame member FM.

The storage container CA1, CA2 may house the frame member FM to which a pellicle film has not been attached or the frame member FM to which a pellicle film has been attached.

The frame member FM may be formed, for example, from metal such as stainless steel, aluminum, copper, or brass, resin such as silicon, fluorine resin, or acrylic resin, or a ceramic material. The shape may be a non-annular shape (a shape having a discontinuous circumference), a circle, an oval, a polygon, or any other shape.

The material, type, shape, and the like of the storage container CA1, CA2, the frame member FM, the storage member AM, and the pellicle film in the invention are not particularly limited. For example, the storage container CA1, CA2, the frame member FM, the storage member AM, and the pellicle film may be in a shape of a circle, an oval, or a polygon such as a triangle or a quadrangle or in any other shape.

Regarding the drive equipment of the above exemplary embodiment, motorized equipment such as a rotary motor, a linear motion motor, a linear motor, a single-axis robot, or a so-called articulated robot having biaxial or tri-or more axial joints, an actuator such as an air cylinder, a hydraulic cylinder, a rodless cylinder, or a rotary cylinder, and the like, may be used alone, or provided by a direct or indirect combination thereof. Or, one capable or incapable of performing a torque control, a speed control, or the like on an output section of the motorized equipment, the actuator, or the like may be used.

In the above exemplary embodiment, an object (hereinafter, referred to as “object A”) and another object (hereinafter, referred to as “object B”) movable with respect to the object A, that is, relatively movable object A and object B may be defined as follows. The object B may be moved with respect to the immovable object A, the object A may be moved with respect to the immovable object B, or both the object A and the object B may be moved. It does not matter which one of the object A and the object B is to be moved insofar as the movement achieves the same result. In a case where there is provided an element, such as a support (retaining) unit or a support (retaining) member, that supports (retains) a member to be supported (a member to be retained), the member to be supported may be supported (retained) by a holding unit such as a mechanical chuck or a chuck cylinder, Coulomb force, an adhesive (an adhesive sheet or an adhesive tape), a sticky agent (a sticky sheet or a sticky tape), magnetic force, Bernoulli suction, vacuum suction, drive equipment, or the like.

What is claimed is

1. A storage container opening/closing device configured to open and close a storage container comprising a storage portion configured to house a frame member to which a pellicle film is attached, and a cover configured to cover the storage portion, the storage container opening/closing device comprising:
a storage container support unit configured to support the storage container; and
an opening/closing unit configured to open and close the storage container by moving the cover, wherein
the opening/closing unit comprises:
a retainer configured to retain the cover;
a first movement unit configured to move the cover retained by the retainer in a direction away from and toward the storage portion; and
a second movement unit configured to tilt the cover retained by the retainer with respect to the storage portion.

2. The storage container opening/closing device according to claim 1, wherein
the frame member is housed in the storage portion via the storage member that houses the frame member,
the storage container opening/closing device further comprising:
a storage member support unit configured to support the frame member and the storage member; and
a transport unit configured to take the frame member and the storage member out of the storage container and transport the frame member and the storage member to the storage member support unit.

3. A storage container opening/closing method for opening and closing a storage container comprising a storage portion configured to house a frame member to which a pellicle film is attached, and a cover configured to cover the storage portion, the method comprising:
supporting the storage container; and
opening and closing the storage container by moving the cover, wherein the opening and closing comprises:
retaining the cover;
moving the cover retained in the retaining in a direction away from and toward the storage portion as a first movement operation; and
tilting the cover retained in the retaining with respect to the storage portion as a second movement operation.
